(19) United States
(12) Patent Application Publication
(10) Pub. No.: US 2020/0043761 A1
(43) Pub. Date: Feb. 6, 2020

(54) SILICON STAMP WITH ETCHED PITS

(71) Applicant: Hewlett-Packard Development Company, L.P., Spring, TX (US)

(72) Inventors: Ning Ge, Palo Alto, CA (US); Ya-Ling Chang, Palo Alto, CA (US); Helen A. Holder, Palo Alto, CA (US)

(73) Assignee: Hewlett-Packard Development Company, L.P., Spring, TX (US)

(21) Appl. No.: 16/340,229

(22) PCT Filed: Oct. 10, 2016
(86) PCT No.: PCT/US2016/056251

§ 371 Date: Apr. 8, 2019

(51) Int. Cl. H01L 21/67; H01L 25/075; H01L 21/68

(52) U.S. Cl. CPC H01L 21/67144; H01L 21/68; H01L 21/67132; H01L 25/0753

(57) ABSTRACT

A stamp for picking and placing multiple components in fixed separations to each other includes: a silicon substrate with a plurality of etched pits, wherein the etched pits correspond to a size and geometry of the components and a metal layer covering an inner surface of the plurality of etched pits.

### BACKGROUND

The continued reductions in the minimum feature size when manufacturing electronic components has produced a number of challenges and opportunities. Smaller sizes have allowed more components to be produced on a wafer of a given size, this has cut the per component cost. For example, if all dimensions are halved then four times as many parts can be manufactured in the same area. However, smaller sizes have presented numerous challenges as well. For example, getting information or power into or out of smaller components has been an ongoing engineering challenge. Similarly, wiring up the components to other components has presented challenges. As part sizes continue to shrink, the picking up the components and placing them in the proper position and orientation has become increasingly challenging. This often referred to as “pick and place” in industry jargon.

### BRIEF DESCRIPTION OF THE DRAWINGS

The accompanying drawings illustrate various examples of the subject matter described herein and are a part of the specification. The illustrated examples are intended to illustrate and do not limit the scope of the claims. Throughout the drawings, identical reference numbers designate similar, but not necessarily identical, elements.

FIGS. 1A and 1B show examples of a stamp tool according to the subject matter described herein.

FIGS. 2A-C show a process flow for picking and placing according to one example of the subject matter described herein.

FIGS. 3A-3E show a process for forming a stamp according to an example of the subject matter described herein.

FIG. 4 shows a flowchart of a method (400) of using a tool according to one example of the subject matter described herein.

FIG. 5 shows an example of a stamp tool according to one example of the subject matter described herein.

FIG. 6 shows a top view of a stamp according to one example of the subject matter described herein.

FIG. 7 shows a side view of a stamp according to one example of the subject matter described herein.

FIG. 8 shows a top view of a stamp (100) according to one example consistent with this disclosure.

FIGS. 9A and 9B show a stamp according to one example described in this specification.

FIG. 10 shows

[symbol]

### DETAILED DESCRIPTION

Picking and placing small components is increasingly difficult as the size of electronic components continues to decrease and the number of items to be placed increases, One relevant area is the production of displays using micro light emitting diodes (microLEDs). At one time, the pixel dimensions in displays were dictated by the size of the light or color producing elements. LEDs were placed as close together as possible to produce the base achievable resolution. However, ongoing miniaturization of LEDs and well as continued increases in brightness have resulted in microLEDs shrinking so as to be smaller than the pixel to pixel spacing.

It would be possible to produce microLEDs on a silicon substrate with the correct spacing, this approach has some challenges. First, it would waste a large percentage of the silicon wafer that was not used to produce the microLEDs. Second, it would involve forming LEDs of different colors on a common wafer resulting in more process operations being performed on a common wafer. Increasing process operations in semiconductor fabrication is generally associated with increased yield loss. Finally, it would drastically increase the scrap/repair costs because the individual LEDs could not be verified before incorporation into the display. Instead, of individual microLEDs being the scrapped component, the combined display area would be the scrapped unit, drastically increasing scrap costs. Accordingly, while this approach could be utilized, generally speaking, manufacturing has moved to producing microLEDs in dense arrays of a single color. The microLEDs are then diced, picked and placed in position to form the display. The microLEDs are then electrically connected to controllers that provide the signals to generate images on the display.

However, as the size of microLEDs have continued to shrink, the difficulty of picking and placing them precisely and efficiently has been a challenge. Consider a pixel on a display, and then consider that most of the area of that pixel is blank space and that the micro LED occupies a fraction of the pixel. It will be apparent that manipulating such small components en masse can be a formidable engineering challenge. This specification describes a tool that facilitates picking and placing components like microLEDs, The stamp includes a silicon substrate with etched pits. The non-flat transfer surfaces of the stamp which include the pits help control the orientation of components being picked and placed, Static charge and/or surface tension are used to pick and hold the components in place on the stamp. The charge is then neutralized or the liquid is evaporated to release the components once the stamp is positioned correctly. This approach allows rapid and efficient picking and placing of components such as microLEDs. This approach controls orientation of the components. This approach uses many existing semiconductor fabrication techniques, minimizing the development and production costs. Finally, this approach is cost effective picking and placing of small components.

Accordingly, the present specification describes, among other examples, a stamp for picking and placing multiple components in fixed separations to each other, the stamp including: a silicon substrate including, a plurality of etched pits, wherein the etched pits correspond to a size and geometry of the components and a metal layer covering an inner surface of the plurality of etched pits.

The present specification also describes a method of picking and placing which includes: bringing a tool into proximity with a plurality of components; attracting the components to the tool via electrostatic interaction between a plurality of transfer surfaces of the tool and the plurality of components, wherein the plurality of transfer surfaces are recessed relative to adjacent portions of the tool; and dropping the plurality of components from the plurality of transfer surfaces of the tool onto a substrate.

The specification also describes a system for placing small components, where the system includes: a silicon substrate with a transfer surface, the transfer surface comprising a plurality of anisotropic etched pits; a fluid distribution system to provide fluid to the plurality of pits; and a heater positioned to heat the plurality of pits.

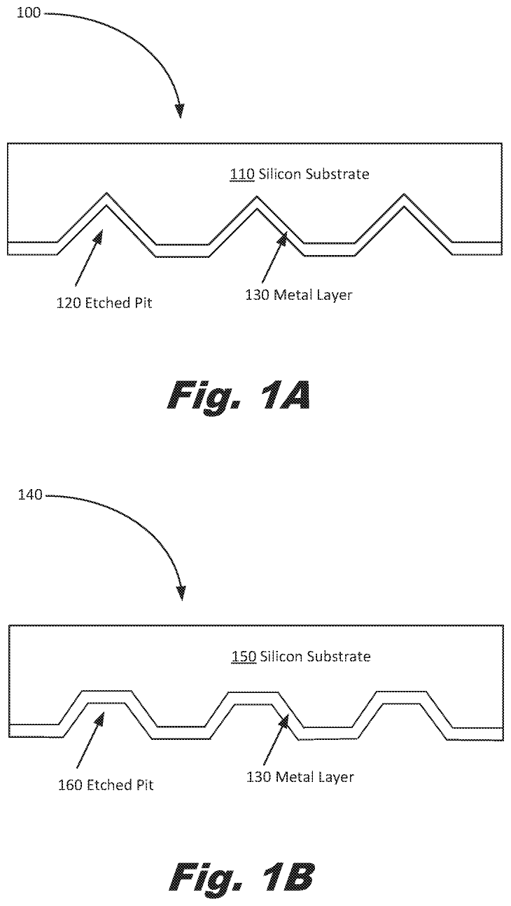

Turning now to the figures, FIG. 1A shows a stamp (100) that includes a silicon substrate (110) with a plurality of etched pits (120) formed in the silicon substrate (110). The etched pits (110) are covered with a metal layer (130).

The stamp (100) is a tool to perform pick and place operations using small components. The stamp (100) includes a silicon substrate (110) with a plurality of etched pits (120). The stamp (100) includes a metal layer (130) that is present on an inner surface of the etched pits (120).

The stamp (100) may function by bringing the stamp into proximity to the parts to be picked up. As static charge may be generated on the stamp (100). The static charge may then attract the parts to be picked to the stamp (120). The use of the etched pits (120) may provide orientation and alignment of the picked parts.

The stamp (100) may have liquid provided to the etched pits. The liquid has a surface tension and may function to adhere the picked parts to the stamp (100). The etched pits (120) may facilitate holding the liquid as they may allow a lower surface energy to volume ratio. In one example, the tool is aligned with the placement location for the parts. The liquid may then be removed, In one example, the liquid is allowed to dry under ambient conditions. The use of a volatile liquid may be selected to provide the desired drying time. For example, ethanol may be selected to allow less time between picking the parts and placing them compared with isopropanol. The liquid may be selected to minimize residuals upon evaporation.

The evaporation of the liquid may be accelerated once the stamp (100) is in the correct position to place the parts. In one example, a thermal resistor is provided that heats the liquid in the etched pits (120). In another example, a heat source is directed at the surface of the stamp. Heat may be provided from the back of the stamp, for example, through the silicon substrate.

The silicon substrate (110) provides some advantages in forming the stamp (100). Commercial silicon wafers are now widely available in excellent purities. Further, the cost continues to decrease, Silicon monocrystalline wafers can be readily processed with a wide range of existing fabrication techniques. This allows the preparation of the stamp (100) using existing and well established techniques, minimizing the R&D costs.

A silicon substrate (110) can be processed to include mechanical features and electronic components. For example, Complementary metal-oxide-semiconductor (CMOS) digital circuits, heaters and other electronic components can be formed in the silicon substrate at the back end of a line process for the substrate (110)

One advantage of silicon as a material for the silicon substrate (110) is the ability to form etched pits (120) of controlled dimensions. For example, as shown in FIG. 1B, a stamp (140) may include etched pits (160) in a silicon substrate (150) with flat bottoms or a v-shaped profile, rather than the pointed profile shown in FIG. 1A. The use of masking and selective etching are available technologies that allow formation of mechanical features with tight tolerances. This allows the formation of etched pits of various configurations. The use of an anisotropic edge may make the pit etching process self-limiting, providing additional control of the final dimensions of the etched pits.

Referring again to FIG. 1A, not all planes of a silicon crystal are equally durable. For example, in anisotropic etching of silicon, the <1 0 0> plane may be more stable and thus resist the etchant. Accordingly, the formation of the etched pits (120) may use the <1 0 0> plane to limit the extent of etching. In one example, at least one surface of the etched pit (120) is an exposed <1 0 0> plane of the silicon substrate (110).

The etched pits (120) include a metal layer (130) on an inner surface of the pit. The metal layer may be charged to produce a static charge on the etched pit (120). The static charge may be used to attract the components to be picked. When the stamp is in position, the static charge can be neutralized, In another example, a charge of opposite polarity can be applied to the metal layer (130). This facilitates detachment of the component from the stamp (100) and placement of the components in the desired position.

The metal layer (130) may be continuous. The metal layer (130) may be patterned. For example, a photoresist layer may be applied over a vapor deposited metal layer. The photoresist layer in then patterned and portions removed. The metal layer under the removed portions is then removed, for example by etching or chemical removal. The photoresist layer is then removed to reveal the patterned metal layer (130). In some examples, the metal layer (130) in individual etched pits (120) can be activated or deactivated selectively.

The use of a silicon substrate (110) allows for the incorporation of logics and control elements into the stamp. These elements may be built into the side of the stamp (100) with the etched pits (120). These elements may be built into opposite side of the stamp (100). The processes for building electronic components and Micro-Electro-Mechanical Systems (MEMS) devices on silicon wafers are readily accessible to those of ordinary skill in the art. In some examples, the logic and control elements are located off the stamp (100) and connected to the stamp (100) through electrical connections. In other examples, the logic and control elements are fabricated on with stamp (100) itself. The tradeoff in this decision reflects, among other factors, the number of additional processing operations to incorporate the logics onto the stamp (100) compared with the space considerations and complexity of making data and power connections between the stamp (100) and off stamp (100) resources.

The metal layers (130) in individual etched pits (120) may be individually addressable and controllable by CMOS circuits built in the silicon substrate (100). Additionally, the metal layer can form or be part of an electronic device such as a heater or an electrostatic discharge (ESD) plate. In one example, different potential is applied to different metal layers (130) in different etched pits (120) on the stamp (100).

The metal layer (130) in each etched pit (120) may be electrically isolatable from each other. The metal layer (130) may be divided into banks of multiple etched pits (120) allowing discrete areas of the stamp (100) to be activated or neutralized independently.

The etched pits (120) may limit the orientation of components that are picked and placed. For example, in one example, the etched pits (120) are pyramidal and the components have a similar pyramidal, conic, or truncated conic shape. The etched pits (120) may have a flat bottom. The components may be able to rotate in one axis while in the etched pit (120) while being constrained in a second axis. For example, a component may be able to spin in place but may be impeded or prevented from rotating in a different axis by the shape of the etched pit (120).

The stamp (100) may include liquid in the plurality of pits, the liquid adhering components to the tool. The stamp (100) may include a thermal resistor positioned to heat the metal layer (130).

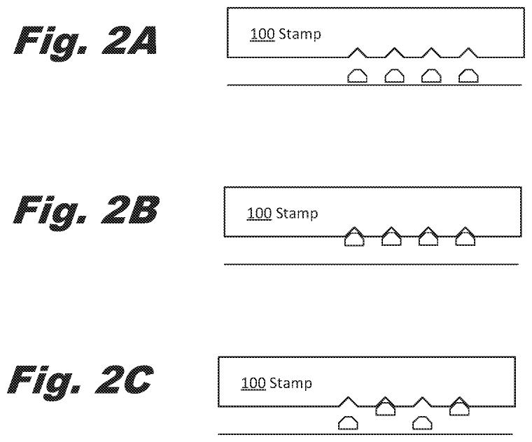

FIGS. 2A-C show a process flow for picking and placing according to one example of the subject matter described herein. FIG. 2A shows a stamp (100) with a plurality of etched pits (120). The stamp (100) is brought close to a group of components.

In FIG. 2B, the components are attracted to the stamp (100). This may be the result of an applied charge to the stamp (100). This may be the result of surface tension from liquid in the etched pits (120). The stamp (100) holds the components and is moved to a different location where the components will be placed.

In FIG. 2C, some of the components have been released from the stamp (100) and are resting on a surface below the stamp. The stamp (100) may apply a potential with an opposite polarity of the static charge used to attract the components. The stamp (100) may allow the liquid to evaporate, allowing the components to fall to the surface. The stamp may heat the liquid to speed up the evaporation of the liquid using a heater.

The process may include applying a static charge to a metal layer (130) lining the plurality of transfer surfaces. The process may include aligning the stamp (100) with respect to the surface. The stamp (100) may include an alignment feature to facilitate positioning of the stamp (100).

The components may be any suitably sized component. In one example, the components are micro light emitting diodes (microLEDs). As shown, the etched pits (120) limit the orientation of the components. The etched pits may be designed to conform to the shape of the components. The etched pits may be sized to limit the orientation of the held components.

The transfer surfaces that hold the components are recessed compared to the adjacent portions of the stamp. The transfer surfaces may be etched pits (120). Specifically, the transfer surfaces may be anisotropic etched pits (120).

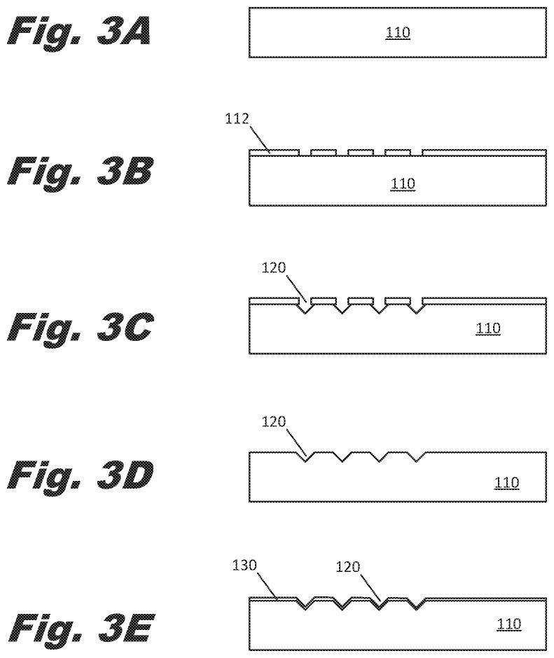

FIGS. 3A-3E show a process for forming a stamp (100) according to an example of the subject matter described herein. FIG. 3A shows a silicon wafer that will form the silicon substrate (110) of the stamp (100). The use of existing wafer processes facilitates lower development costs. The use of existing wafer processes can also take advantage of economies of scale to further reduce stamp (100) costs.

FIG. 3B shows a mask (112) applied to a surface of the silicon substrate (110). The mask may be a photoresist mask. The mask may be a positive photoresist. The mask may be a negative photo resist. The mask may be an applied or adhered mask.

FIG. 3C shows the etched pits (120) formed by etching through the mask. The pits are distributed according to the patterning of the mask. Etch time and depth are controlled to form the etched pits into the desired shape (120). In some examples, the etched pits (120) are shaped to conform to the parts that will be picked and placed with the stamp, A layer of non-conductive material may be formed or deposited on the surface of the silicon substrate (110). This may be, for example, silicon oxide, silicon carbide, silicon nitride. A deposited layer may be, for example, a vapor deposited insulator.

FIG. 3D shows the silicon substrate (110) after the mask has been removed. The method of mask removal may be selected based on the type of mask being used. In some examples, the silicon substrate (110) with the etched pits (120) formed in the silicon substrate (110) maybe subjected to additional processing before the next operation.

FIG. 3E shows a metal layer (130) applied to the silicon substrate (110), including to the inner surfaces of the etched pits (120). Metallization can be accomplished using a variety of processes and technologies. For example, vapor deposition of metal layers is commonly available as part of semiconductor fabrication.

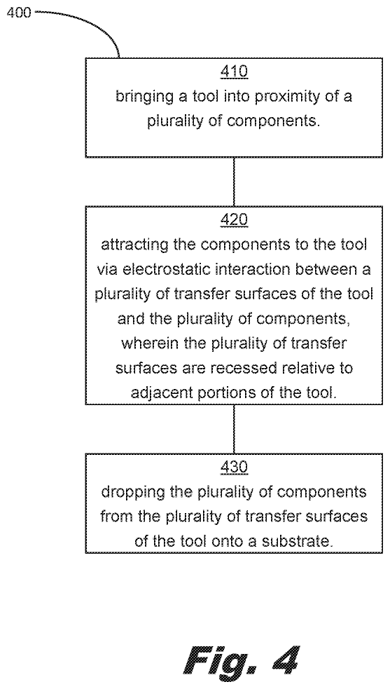

FIG. 4 shows a flowchart of a method (400) of using a tool according to one example of the subject matter described herein. The method includes: bringing a tool into proximity of a plurality of components (410); attracting the components to the tool via electrostatic interaction between a plurality of transfer surfaces of the tool and the plurality of components, wherein the plurality of transfer surfaces are recessed relative to adjacent portions of the tool (420); and dropping the plurality of components from the plurality of transfer surfaces of the tool onto a substrate (430).

The method (400) includes bringing the tool into proximity to a plurality of components (410). This is part of picking the components. The components may be regularly spaced or positioned. In one example, the components are formed on a silicon substrate using semiconductor processing operations. The components are then diced into individual components or clusters of components for transfer. For example, micro light emitting diodes (microLEDs) are produced with a first density but are transferred and placed in a second, lower density as part of producing screens or similar devices.

The method (400) also includes attracting the components to the tool via electrostatic interaction between a plurality of transfer surfaces of the tool and the plurality of components, wherein the plurality of transfer surfaces are recessed relative to adjacent portions of the tool (420). As discussed above, the use of recessed portions of the transfer surfaces provides orientation control and greater contact area between the transfer surface and the component. This can reduce needing to perform secondary adjustments to the placed component after placement. The greater contact and control can increase the reproducibility of picking and placing, reducing costs and manufacturing defects along with the associated rework or scrap.

The method (400) includes dropping the plurality of components from the plurality of transfer surfaces of the tool onto a substrate (430). The plurality of components may be dropped simultaneously or sequentially. In one example, the components are dropped by registers or banks of recessed transfer surfaces. The tool may be loaded with components into each of the transfer surfaces, drop some of the components, and then move to a new location before dropping other components. In one example the tool includes the ability to load all the transfer surfaces simultaneously. This may reduce the time to perform the pick and place operations. This may also facilitate loading more components on the tool, reducing the number of cycles to pick and place a given number of components. In one example the spacing of the recessed transfer surfaces is dependent upon the manufacturing density of the components such that a region of manufactured and diced components can be picked either simultaneously or in succession.

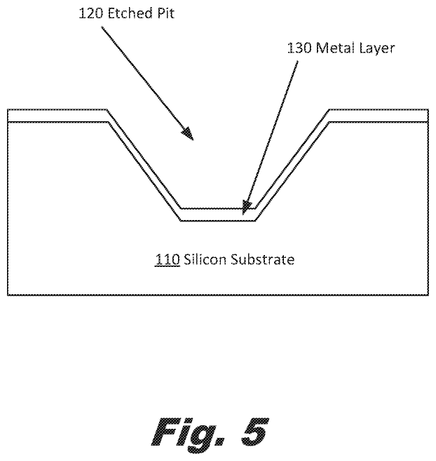

FIG. 5 shows an example of a stamp tool according to one example of the subject matter described herein. The stamp tool includes a silicon substrate (110) with a plurality of etched pits (120). The etched pits (120) include a metal layer (130) that covers at least a portion of the walls of the etched pits (120). The etched pit (120) shows a flat bottom. This allows different geometries compared with the pyramidal or conical etched pits (120). The flat bottom etched pit (120) may use a larger opening in the mask during etching and controlling the etching time to produce the desired etched pit geometry (120).

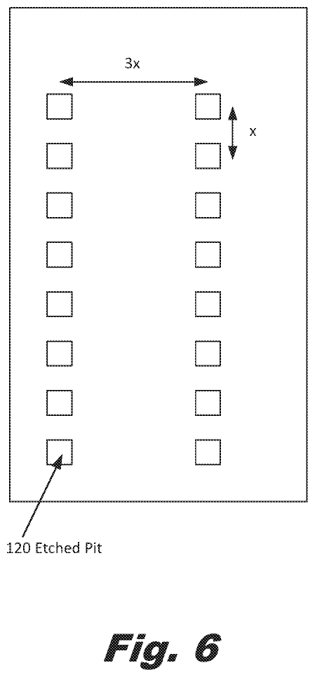

FIG. 6 shows a top view of a stamp according to one example of the subject matter described herein. The stamp shows a plurality of etched pits (120) in a silicon substrate (110). The etched pits (120) are organized with a first spacing in one axis and a second spacing in a second, perpendicular axis. In FIG. 6 the spacing ratio is x is one direction and 3x is the second direction. However, other spacing and patterns of the etched pits (120) may be similarly contemplated, including the use of the same spacing in two perpendicular directions and where the spacing in one axis is not a whole number multiple of the other.

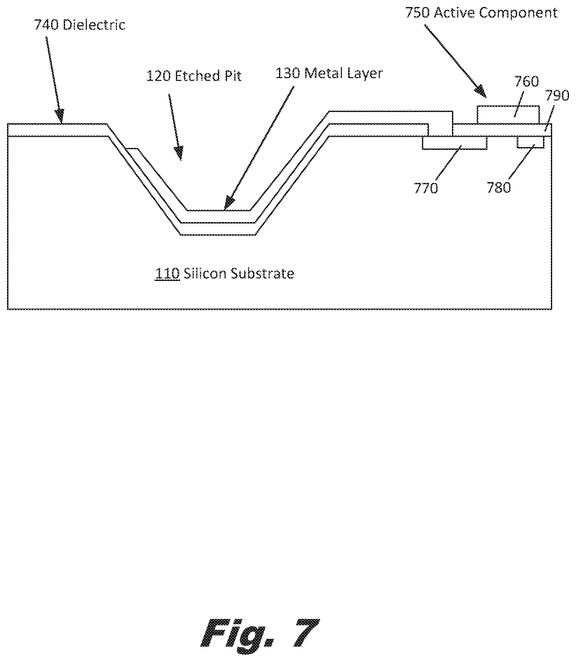

FIG. 7 shows a side view of a stamp according to one example of the subject matter described herein. The stamp (100) has a silicon substrate (110) with an etched pit (120). A dielectric layer (740) separates a metal layer (130) from the silicon substrate (110). An active component (750) is mounted on the dielectric layer (740) and provides control of potential applied to the metal layer (130). Electrical connections are shown under and passing through the dielectric layer (740). The electrical connections provide power and communication between the active components (750) and the metal layers (13) in on the inner surfaces of the etched pits (120).

In an example, the active component (750) is a MOSFET transistor. The transistor (750) includes a gate (760), a source (780) and a drain (770). A gate oxide layer (790) separates the gate (760) from the source (780) and drain (770).

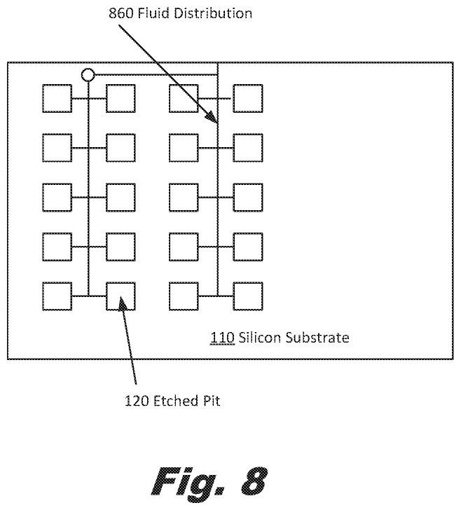

FIG. 8 shows a top view of a stamp (100) according to one example consistent with this disclosure. The stamp (100) includes a silicon substrate (110) with a plurality of etched pits (120). The etched pits (120) are connected to a fluid distribution (860) system.

The fluid distribution (860) system provides liquid to the etched pits (120). The liquid facilitates holding the components due to the surface tension of the liquid. The fluid distribution (860) may include a variety of liquid slots, trenches, tubes, channels, textures, surfaces, etc. to facilitate movement of the liquid to the etched pits (120). In one example, the fluid distribution (860) system is etched into the silicon substrate (110), either as part of forming the etched pits (120) or using a secondary operation. The fluid distribution (860) system may include a reservoir on the stamp (100). The fluid distribution (860) system may include a via through the silicon substrate to provide liquid to the fluid distribution (860) system. The stamp (100) may include a plurality of via in the silicon substrate (110).

The stamp (100) with a fluid distribution system (860) may be used in a variety of applications. For example, a stamp (100) with a fluid distribution system (860) as described herein may form, or be incorporated in, a fluidic MEMS device such as an inkjet printhead.

The fluid distribution (860) system may include active pumping. The fluid distribution (860) may use capillary action, that is to say, wetting, to move fluid. The fluid distribution (860) system may use potentials to regulate liquid or the movement of liquid.

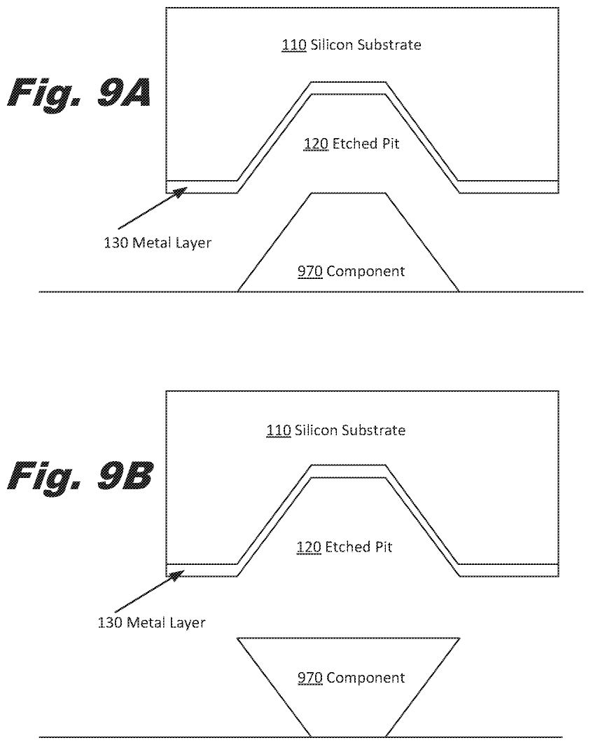

FIGS. 9A and 9B show a stamp according to one example described in this specification. In FIG. 9A, the stamp (100) includes a silicon substrate (110) with an etched pit (120). The etched pit (120) includes a metal layer (130) on an inside surface of the etched pit (120). Also shown is a component (970) to be picked up by the stamp (100). In FIG. 9A, the component orientation is such that the etched pit (120) conforms to the shape of the component (970).

In FIG. 9B, the stamp (100), silicon substrate (110), etched pit (120), metal layer (130), and component (970) are present, however, the orientation of the component (970) is different. In some examples, the amount of static charge applied to the metal layer (130) is such that a component (970) in the orientation of FIG. 9A will be attracted to and retained by the etched pit (120) while the component (970) oriented as in FIG. 9B will not be retained. This matching of the component (970) orientation allows reproducible control over the orientation of the component (970) when it is placed. This may reduce the need for a secondary adjustment or rework. The correlation of the component (970) shape and the shape of the etched pit (120) may also allow for selective loading of the stamp (100) with the components (970) from among a group of small objects. In contrast, the use of a flat transfer surface does not provide this kind of orientation control.

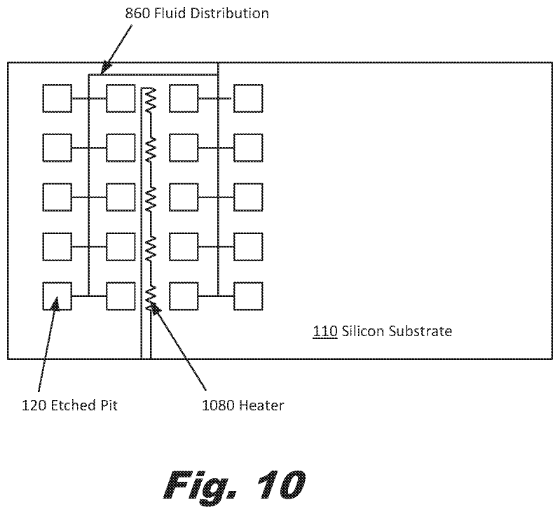

FIG. 10 shows a top view of a stamp (100) according to one example consistent with this disclosure. The stamp (100) includes a silicon substrate (110) with a plurality of etched pits (120). The etched pits (120) are connected to a fluid distribution (860) system. A heater (1080) is also shown in proximity to the etched pits (120).

The heater (1080) may be a resister. For example, resistors, such as those used in a thermal ink jet printhead, may be readily fabricated on a silicon substrate. The heaters (1080) may be arranged in a bank as shown in FIG. 10. The heaters (1080) may be individually controlled and capable of independent activation. The heaters (1080) heat the metal layer (130) and/or the silicon substrate (110). This may be used to accelerate evaporation of liquid provided by the fluid distribution (860) system. This may accelerate the evaporation of fluid in the etched pits (120) causing release of held components (970). Other types of heaters may be used, including heat exchangers, infra-red heaters, and chemical heaters (1080). The heaters (1080) may be located on the other side of the silicon substrate (110) and the heat propagated through the silicon substrate (110). Some advantages of resistor heaters (1080) are the ability to rapidly turn the heater on and off, the short response times, the manufacturing experience from thermal ink jets, the flexibly in shape and size, and the ability to produce them on silicon substrates with few additional process operations.

FIG. 10 shows the fluid distribution (860) system and the heaters provided from opposite sides of the stamp (100). While this configuration has advantages in avoiding overlap and minimizing manufacturing difficulties, other configurations are possible. For example, the fluid distribution (860) can be provided through the silicon substrate (110) using vias. The heaters (1080) and associated electrical elements may be sequestered in a lower layer of the silicon substrate (110) for example with an insulating layer between them and the fluid distribution (860) system. This approach allows more complex geometries compared with bring in the electrical and the liquid from different sides of the stamp (100). Accordingly, tradeoffs between design simplicity, manufacturing operations, cost, and similar concerns will influence the approach for any given design.

In some examples, the heaters (1080) include a plurality of thermal resistors. The stamp (100) may also include a logic device or logic devices to control the application of current to the heaters (1080).

While representative examples and designs have been shown to aid the understanding of this disclosure, the subject matter of this disclosure is not limited to those elements or configurations explicitly shown in the figures. Accordingly, this application also discloses the variations and configurations that would be apparent to a person of ordinary skill in the art upon review and consideration of the figures, description, and principles recited.

What is claimed is:

1. A stamp for picking and placing multiple components in fixed separations to each other, the stamp comprising:
a silicon substrate comprising, a plurality of etched pits, wherein the etched pits correspond to a size and geometry of the components; and
a metal layer covering an inner surface of the plurality of etched pits.

2. The stamp of claim 1, wherein the metal layers of each pit are electrically isolatable from each other.

3. The stamp of claim 1, wherein the pits limit the orientation of the components in one axis.

4. The stamp of claim 1, wherein a <1 0 0> plane of the silicon substrate forms a surface of an etched pit of the plurality of etched pits, the plurality of etched pits being formed with an an-isotropic etch.

5. The stamp of claim 1, further comprising a plurality of logics to regulate a potential of the metal layer in individual pits.

6. The stamp of claim 1, further comprising a liquid in the plurality of pits, the liquid adhering components to the tool in the pits.

7. The stamp of claim 1, further comprising a thermal resistor positioned to heat the metal layer.

8. A method of picking and placing, comprising:
bringing a tool into proximity with a plurality of components;
attracting the components to the tool via electrostatic interaction between a plurality of transfer surfaces of the tool and the plurality of components, wherein the plurality of transfer surfaces are recessed relative to adjacent portions of the tool; and
dropping the plurality of components from the plurality of transfer surfaces of the tool onto a substrate.

9. The method of claim 8, further comprising, applying a static charge to a metal layer lining the plurality of transfer surfaces

10. The method of claim 8, further comprising, aligning the tool with respect to the substrate, wherein the tool comprises alignment features to facilitate positioning with respect to the substrate.

11. The method of claim 8, wherein the components are micro Light Emitting Diodes (microLEDs).

12. The method of claim 8, wherein the transfer surfaces limit possible orientations of the components held by the tool.

13. The method of claim 8, wherein the recessed transfer surfaces comprise anisotropic etched pits in a silicon substrate.

14. A system for placing small components, comprising:
a silicon substrate with a transfer surface, the transfer surface comprising a plurality of anisotropic etched pits;
a fluid distribution system to provide fluid to the plurality of pits; and
a heater positioned to heat the plurality of pits.

15. The system of claim 14, further comprising:
a plurality of thermal resistors distributed among the pits; and
a logic device to regulate application of current to the plurality of resistors.
